(19) United States
(12) Patent Application Publication
(10) Pub. No.: US 2015/0214127 A1
(43) Pub. Date: Jul. 30, 2015

(54) INTEGRATED DEVICE COMPRISING A SUBSTRATE WITH ALIGNING TRENCH AND/OR COOLING CAVITY

(71) Applicant: QUALCOMM Incorporated, San Diego, CA (US)

(72) Inventors: Shiqun Gu, San Diego, CA (US); Ratibor Radojcic, San Diego, CA (US); Dong Wook Kim, San Diego, CA (US)

(73) Assignee: QUALCOMM Incorporated, San Diego, CA (US)

(21) Appl. No.: 14/162,969

(22) Filed: Jan. 24, 2014

(51) Int. Cl. H01L 23/367; H01L 23/544; H01L 23/00

(52) U.S. Cl. CPC H01L 23/367; H01L 24/83; H01L 24/32; H01L 23/544; H01L 2223/54426; H01L 2224/8385; H01L 2924/1015; H01L 2224/32225

(57) ABSTRACT

Some features pertain to an integrated device that includes a substrate. The substrate includes a first cavity (e.g., trench). The first cavity includes a first edge that is non-vertical. The first cavity is configured to align a die towards a center of the first cavity when the die is placed off-center of the first cavity. The integrated device also includes a first die positioned in the first cavity. The integrated device further includes a redistribution portion coupled to the first die. In some implementations, the first edge is a first wall of the first cavity. In some implementations, the first cavity includes a first opening and a first base portion. The first opening of the first cavity is greater than the first base portion of the first cavity.

### BACKGROUND

1. Field

Various features relate to an integrated device that includes a substrate with aligning trench and/or cooling cavity.

2. Background

Alignment issues during the manufacturing of an integrated device can cause defective integrated devices, which adversely affects manufacturing yields. FIG. 1 conceptually illustrates an integrated device 100 that includes several dies, where the integrated device is defective because of a misalignment. As shown in FIG. 1, the integrated device 100 includes a substrate 101, a first die 102, a second die 104, a dielectric layer 106, a mold 107, a first set of redistribution layers 108, a second set of redistribution layers 110, a third set of redistribution layers 112, a first under bump metallization (UBM) layer 118, a second under bump metallization (UBM) layer 120, a first solder ball 128, and a second solder ball 130

Each of the first, second, and third sets of redistribution layers 108, 110, and 112 may include one or more interconnects (e.g., metal layers) and/or one or more vias. The first die 102 includes a first bump 140 and a second bump 142. The second die 104 includes a first bump 150 and a second bump 152.

One major concern to coupling dies to a substrate is the misalignment of the connections (e.g., electrical connections) in the integrated package, which can result in a defective integrated device.

As shown in FIG. 1, the first bump 140 of the first die 102 is coupled to the first set of redistribution layers 108. The second bump 142 of the first die 102 is coupled to the third set of redistribution layers 112. FIG. 1 also shows that the first bump 150 of the second die 104 is coupled to the third set of redistribution layers 112. However, FIG. 1 illustrates that the second set of redistribution layers 110 is not electrically coupled to the second bump 152 of the second die 104. Since there is no electrical coupling between the second die 104 and the second set of redistribution layers 110, the second die 104 cannot operate, and thus the integrated package 100 is defective.

Another area of concern for an integrated package is that heat can build up quite easily in the integrated package, especially when two or more dies are inside the integrated package. A build up in heat in an integrated package can cause a die to malfunction and/or break down.

Therefore, in view of the above, there is a need for an integrated package design that provides better alignment of dies in the package, as well as improved heat dissipation.

### SUMMARY

Various features, apparatus and methods described herein provide an integrated device that includes a substrate with aligning trench and/or cooling cavity.

A first example provides an integrated device that includes a substrate. The substrate includes a first cavity. The first cavity includes a first edge that is non-vertical. The first cavity is configured to align a die towards a center of the first cavity when the die is placed off-center of the first cavity. The integrated device also includes a first die positioned substantially in a center of the first cavity.

According to an aspect, the first edge is a first wall of the first cavity.

According to one aspect, the first cavity includes a first opening and a first base portion, wherein the first opening of the first cavity is greater than the first base portion of the first cavity.

According to an aspect, the integrated device further includes a redistribution portion coupled to the first die.

According to one aspect, the first die comprises one of at least rounded edges and/or beveled edges.

According to an aspect, the integrated device further includes an adhesion layer between the first die and the substrate, wherein the adhesion layer is configured to couple the first die to the substrate.

According to one aspect, the integrated device further includes a second cavity in the substrate. The second cavity is positioned in the substrate such that the second cavity is coupled to the first cavity, and the second cavity is between a base portion of the first cavity and a surface of the substrate.

According to an aspect, the integrated device further includes a heat sink embedded in the substrate, where the heat sink is embedded in the substrate such that the heat sink is between a base portion of the first cavity and a surface of the substrate.

According to one aspect, the integrated device is one of at least a semiconductor device, an integrated package and/or a die package.

According to an aspect, the integrated device is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

A second example provides an apparatus that includes a substrate comprising a first die aligning means. The first die aligning means is configured to align a die towards a center of the first die aligning means when the die is placed off-center of the die aligning means. The apparatus also includes a first die positioned substantially in a center of the first die aligning means.

According to an aspect, the first die aligning means includes a first wall that is non-vertical.

According to one aspect, the first cavity includes a first opening and a first base portion, where the first opening of the first cavity is greater than the first base portion of the first cavity.

According to an aspect, the apparatus further includes a redistribution portion coupled to the first die.

According to one aspect, the first die comprises one of at least rounded edges and/or beveled edges.

According to an aspect, the apparatus further includes an adhesive means between the first die and the substrate, wherein the adhesive means is configured to couple the first die to the substrate.

According to one aspect, the apparatus further includes a cooling means in the substrate. The cooling means is positioned in the substrate such that the cooling means is coupled to the first die aligning means, and the cooling means is between a base portion of the first die aligning means and a surface of the substrate.

According to one aspect, the apparatus further includes a heat dissipating means embedded in the substrate, where the heat dissipating means is embedded in the substrate such that the heat dissipating means is between a base portion of the first die aligning means and a surface of the substrate.

According to an aspect, the apparatus is one of at least a semiconductor device, an integrated package and/or a die package.

According to one aspect, the apparatus is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

A third example provides a method for providing an integrated device. The method provides a substrate. The method also provides a first cavity in the substrate, where the first cavity includes a first edge that is non-vertical. The method further provides a first die such that the first die is positioned in the first cavity.

According to an aspect, the first cavity is configured to align a die towards a center of the first cavity when the die is placed off-center of the first cavity.

According to one aspect, the first cavity includes a first opening and a first base portion, where the first opening of the first cavity is greater than the first base portion of the first cavity.

According to an aspect, the method further provides a redistribution portion such that the redistribution is coupled to the first die.

According to one aspect, the first die comprises one of at least rounded edges and/or beveled edges.

According to an aspect, the method further provides an adhesion layer between the first die and the substrate such that the adhesion layer is configured to coupled the first die to the substrate.

According to one aspect, the method further provides a second cavity in the substrate. The second cavity is positioned in the substrate such that the second cavity is coupled to the first cavity, and the second cavity is between a base portion of the first cavity and a surface of the substrate.

According to an aspect, the method further provides a heat sink such that the heat sink is embedded in the substrate. The heat sink is embedded in the substrate such that the heat sink is between a base portion of the first cavity and a surface of the substrate.

According to one aspect, the integrated device is one of at least a semiconductor device, an integrated package and/or a die package.

According to an aspect, the integrated device is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

### DRAWINGS

Various features, nature and advantages may become apparent from the detailed description set forth below when taken in conjunction with the drawings in which like reference characters identify correspondingly throughout.

FIG. 1 illustrates a profile view of a conventional integrated package.

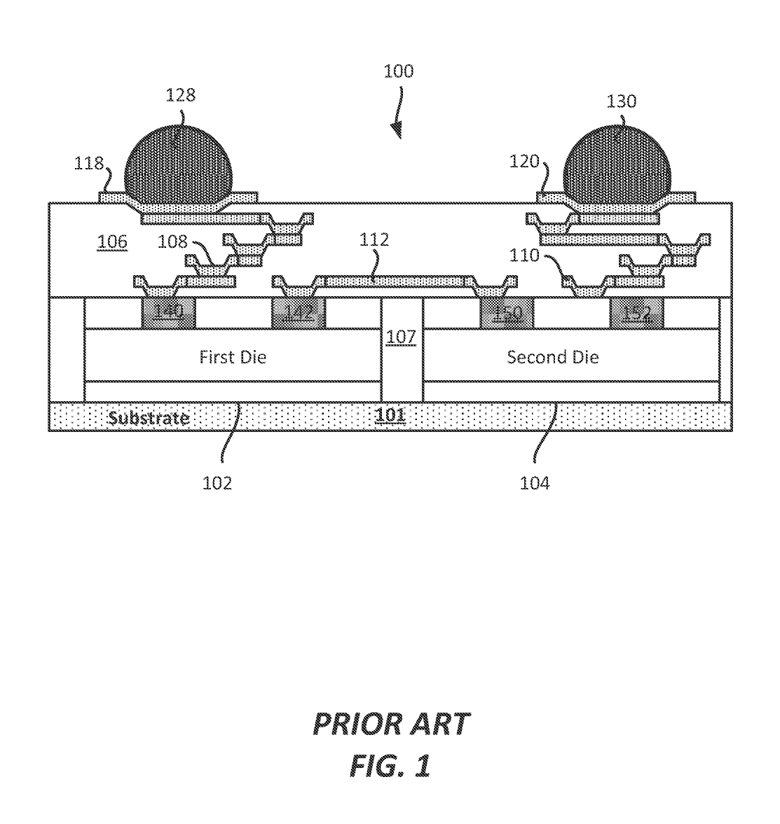

FIG. 2 illustrates an example of an integrated device that includes an aligning cavity.

FIG. 3 illustrates an example of a die.

FIG. 4 illustrates a sequence of how an aligning cavity may align a die towards a center of the cavity.

FIG. 5 illustrates an example of an integrated device that includes an aligning cavity.

FIG. 6 illustrates an example of an integrated device that includes an aligning cavity and adhesion bonding.

FIG. 7 illustrates an example of an integrated device that includes cooling enhancements.

FIG. 8 illustrates an example of an integrated device that includes cooling enhancements and adhesion bonding.

FIG. 9A illustrates part of an exemplary sequence for providing/manufacturing an integrated package.

FIG. 9B illustrates part of an exemplary sequence for providing/manufacturing an integrated package.

FIG. 9C illustrates part of an exemplary sequence for providing/manufacturing an integrated package.

FIG. 10A illustrates part of an exemplary sequence for providing/manufacturing an integrated package.

FIG. 10B illustrates part of an exemplary sequence for providing/manufacturing an integrated package.

FIG. 10C illustrates part of an exemplary sequence for providing/manufacturing an integrated package.

FIG. 11 illustrates an exemplary method for providing/manufacturing an integrated package.

FIG. 12 illustrates various electronic devices that may integrate a semiconductor device, a die, an integrated circuit and/or PCB described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

### Overview

Some novel features pertain to an integrated device (e.g., semiconductor device, integrated package, die package) that includes a substrate. The substrate includes a first cavity (e.g., trench). The first cavity includes a first edge that is non-vertical. The first cavity is configured to align a die towards a center of the first cavity when the die is initially placed off-center of the first cavity. The integrated device also includes a first die positioned substantially in a center of the first cavity. The integrated device further includes a redistribution portion coupled to the first die. In some implementations, the first edge is a first wall of the first cavity. In some implementations, the first cavity includes a first opening and a first base portion. The first opening of the first cavity is greater than the first base portion of the first cavity. In some implementations, the substrate further includes a second cavity. The second cavity includes a second edge that is non-vertical. In some implementations, the integrated device also includes a second die positioned in the second cavity. The redistribution portion is coupled to the second die. In some implementations, the integrated device also includes a second cooling cavity in the substrate. The second cooling cavity is positioned in the substrate such that the second cooling cavity is coupled to the first cavity. The second cooling cavity is between a base portion of the first cavity and a surface of the substrate. In some implementations, the second cooling cavity is configured to dissipate heat away from the first die. In some implementations, the integrated device also includes a heat sink embedded in the substrate. The heat sink is embedded in the substrate such that the heat sink is between a base portion of the first cavity and a surface of the substrate. In some implementations, the heat sink is configured to dissipate heat away from the first die. In some implementations, the first die has rounded edges.

Exemplary Integrated Device that Includes Aligning Cavity

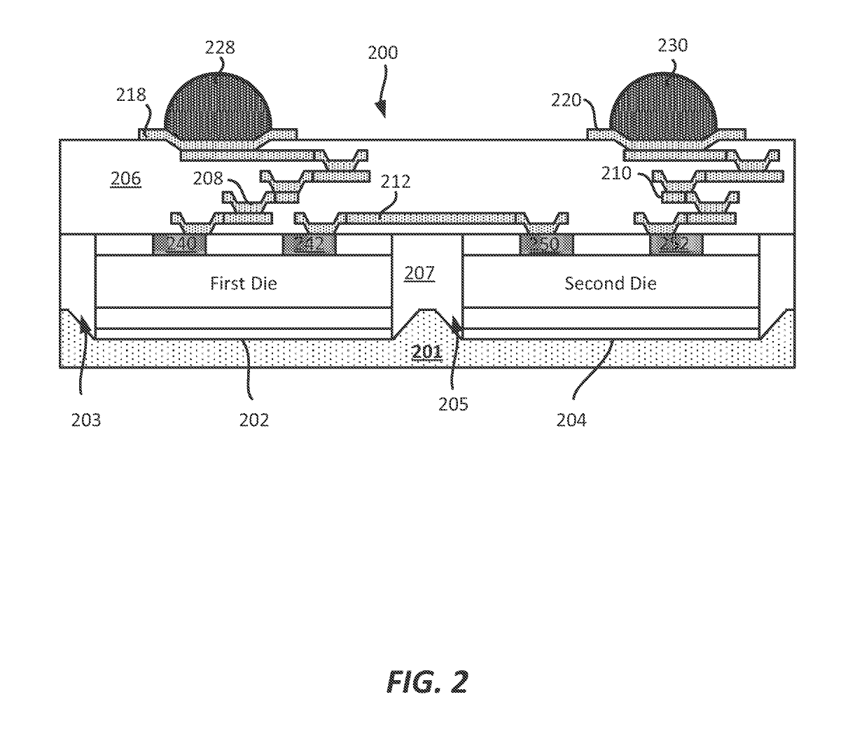

FIG. 2 conceptually illustrates an integrated device 200 that includes several dies, where the integrated device includes one or more aligning cavities (e.g., aligning trenches). In some implementations, an aligning cavity is a cavity that is configured to align a die towards a center of the cavity when the die is initially placed off-center of the cavity. As shown in FIG. 2, the integrated device 200 (e.g., semiconductor device, integrated package) includes a substrate 201, a first integrated device 202 (e.g., first die, first chip), a second integrated device 204 (e.g., second die, second chip), a dielectric layer 206, an encapsulation layer 207 (e.g., mold), a first set of redistribution layers 208, a second set of redistribution layers 210, a third set of redistribution layers 212, a first under bump metallization (UBM) layer 218, a second under bump metallization (UBM) layer 220, a first solder ball 228, and a second solder ball 230. In some implementations, the first and second UBMs 218 and 220 are optional.

Different implementations may use different materials for the substrate 201. For example, in some implementations, the substrate 201 may be one of at least silicon, glass, ceramic and/or dielectric. In some implementations, the dielectric layer 206, the first set of redistribution layers 208, the second set of redistribution layers 210, the third set of redistribution layers 212, the first under bump metallization (UBM) layer 218, and/or the second under bump metallization (UBM) layer 220 are part of and/or in a redistribution portion of the integrated device 200.

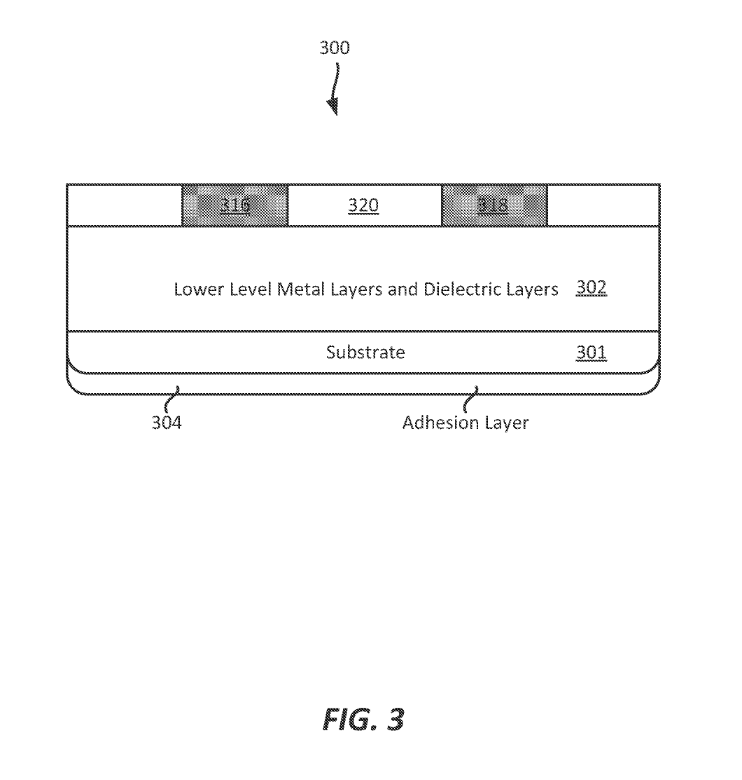

In some implementations, the dielectric layer 206 includes several dielectric layers. In some implementations, each of the first, second, and third sets of redistribution layers 208, 210, and 212 may include one or more interconnects (e.g., metal layers) and/or one or more vias. The first integrated device 202 includes a first interconnect 240 (e.g., first bump, first pillar) and a second interconnect 242 (e.g., second bump, second pillar). The second integrated device 204 includes a first interconnect 250 (e.g., first bump, first pillar) and a second interconnect 252 (e.g., second bump, second pillar). An example of an integrated device (e.g., device 202, device 204) is further described below with respect to FIG. 3.

The substrate 201 includes a first cavity 203 (e.g., first trench) and a second cavity 205 (e.g., second trench). The first integrated device 202 is located in the first cavity 203. The second integrated device 204 is located in the second cavity 205. As shown in FIG. 2, in some implementations, the first and second cavities 203 & 205 have non-vertical edges (e.g., non-vertical walls). In some implementations, a non-vertical edge/wall is an edge or wall that is not perpendicular to a surface of the substrate (e.g., non-perpendicular to surface of the substrate that is not a side of the substrate, top surface, and/or bottom surface). In some implementations, the edge or wall of the first and second cavities 203 & 205 are at a non-perpendicular angle or non-vertical angle.

In some implementations, the first cavity 203 has an opening and a base portion. In the some implementations, the opening of the first cavity 203 is greater (e.g., wider, longer) than the base portion of the first cavity 203. In some implementations, a surface area of the opening of the first cavity 203 is greater (e.g., wider, longer) than a surface area of the base portion of the first cavity 203.

In some implementations, the second cavity 205 has an opening and a base portion. In the some implementations, the opening of the second cavity 205 is greater (e.g., wider, longer) than the base portion of the second cavity 205. In some implementations, a surface area of the opening of the second cavity 205 is greater (e.g., wider, longer) than a surface area of the base portion of the second cavity 205.

In some implementations, the configuration of the first and second cavities 203 & 205 as described above, allows an integrated device (e.g., chip, die) to self-align in the cavities. In some implementations, the cavity (e.g., cavities 203 & 205) may be configured to align a die towards a center of the cavity when the die is initially placed off-center of the cavity.

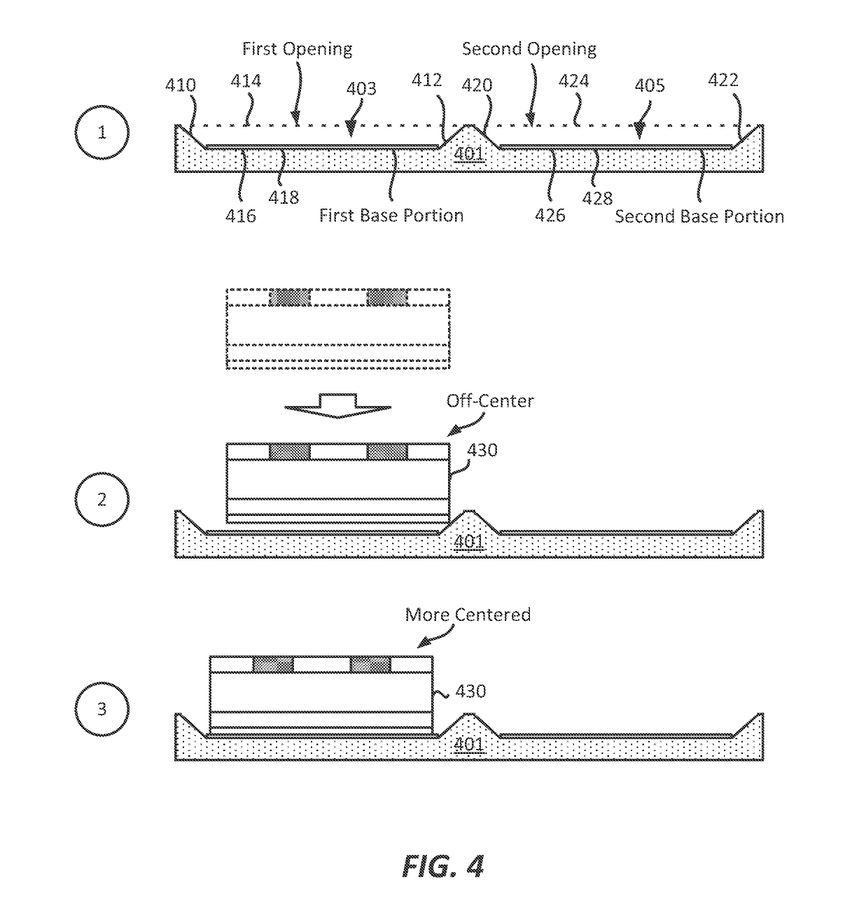

In some implementations, this self-alignment of the integrated devices in the cavities substantially reduces the likelihood of misalignment of integrated devices in an integrated package. An example of self-alignment of a die and/or chip in an integrated device will be further described below in FIG. 4.

As a result of this self-alignment of the dies in an integrated package, connections in the integrated device 200 are properly coupled. As shown in FIG. 2, the first interconnect 240 of the first integrated device 202 is coupled to the first set of redistribution layers 208. The second interconnect 242 of the first integrated device 202 is coupled to the third set of redistribution layers 212. FIG. 2 also shows that the first interconnect 250 of the second integrated device 204 is coupled to the third set of redistribution layers 212. FIG. 2 further illustrates that the second set of redistribution layers 210 is coupled to the second interconnect 252 of the second integrated device 204.

FIG. 3 conceptually illustrates an example of a die 300 (which is a form of an integrated device). For purpose of clarity, FIG. 3 illustrates a generalization of a die. As such, not all the components of a die are shown in FIG. 3. In some implementations, the die 300 may correspond to the first integrated device 202 and/or the second integrated device 204 of FIG. 2. As shown in FIG. 3, the die 300 (e.g., integrated device) includes a substrate 301, several lower level metal layers and dielectric layers 302, an adhesion layer 304 (e.g., oxide layer), a first interconnect 316 (e.g., first bump, first pillar interconnect), a second interconnect 318 (e.g., second bump, second pillar interconnect), and a encapsulation layer 320 (e.g., mold). In some implementations, the die 300 may also include pads, a passivation layer, a first insulation layer, a first under bump metallization (UBM) layer, and a second under bump metallization (UBM) layer. In such instances, the pad may be coupled to the lower level metal layers and dielectric layers 302. A passivation layer may be positioned between the lower level metal layers and dielectric layers 302 and the encapsulation layer 320. A first bump layer may be coupled to the pad and one of the interconnects (e.g., interconnects 316, 318).

The adhesion layer 304 (e.g., adhesion layer) is an optional layer that may be added on the backside of the die. In some implementations, the adhesion layer 304 is provided on the substrate 301 by using a plasma process that exposes the substrate 301 to oxygen and/or nitrogen. In some implementations, the adhesion layer 304 helps the die 300 bond with another component of an integrated device.

In some implementations, the edges and/or corners of the die 300 may have beveled and/or rounded edges. In some implementations, the beveled and/or rounded edges may help the die 300 slide more easily down and angled cavity, which will be further described below in FIG. 4. In some implementations, these beveled and/or rounded edges may be located at the corner/edges of the substrate 301 and/or the adhesion layer 304.

Dies are typically manufactured from wafers, which are then cut (e.g., singulate) into individual dies. Different implementations may singulate the wafer into individual dies differently. In some implementations, a combination of a laser and a saw may be used to mechanically cut the wafer into singular dies. However, the saw is subject to mechanical vibration, which makes it difficult to control the position of the saw. As a result, the die size may vary by as much as 10-20 microns (μm) when a mechanical saw is used. In some instances, the thickness of the wafer may be sufficiently thin enough that the wafer may be cut into individual dies by using lithography and etching process (e.g., dry etch). When such lithography and etching processes are used to singulate the wafer, the variation in the die size can be less than 1 microns (μm). This is important because it can ensure that the die size is less than size of the cavity in the substrate.

In some implementations, one or more redistribution layers (e.g., redistribution layers 208) are coupled to the die 300 through the first interconnect 316 and/or the second interconnect 318. It should be noted that different implementations may have different numbers of interconnects (e.g., more than 2 interconnects).

Having described an integrated device (e.g., integrated package, die package) that includes aligning cavities, aligning cavities that align dies in the integrated package will now be further described in detail below in FIG. 4.

### Self Alignment of Dies in an Integrated Package

As described above, in some implementations, cavities in a substrate of an integrated package allow for one or more dies to self-align in a substrate. FIG. 4 illustrates a sequence of how a die that is positioned in a substrate may self-align. In some implementations, a cavity may be configured to align a die towards a center of the cavity when the die is initially placed off-center of the cavity.

As shown in FIG. 4, at stage 1, a substrate 401 is provided. The substrate 401 includes a first cavity 403 (e.g., first trench) and a second cavity 405 (e.g., second trench). The first cavity 403 includes a first edge 410 (e.g., first wall) and a second edge 412 (e.g., second wall). The second cavity 405 includes a first edge 420 (e.g., first wall) and a second edge 422 (e.g., second wall). As shown in FIG. 4, in some implementations, the first and second cavities 403 & 405 have non-vertical edges (e.g., non-vertical walls). In some implementations, a non-vertical edge/wall is an edge or wall that is not perpendicular to a surface of the substrate (e.g., non-perpendicular to surface of the substrate that is not a side of the substrate, top surface, and/or bottom surface). In some implementations, the edge or wall of the first and second cavities 403 & 405 are at a non-perpendicular angle or non-vertical angle.

In some implementations, the first cavity 403 has a first opening 414 and a first base portion 416. In the some implementations, the first opening 414 of the first cavity 403 is greater (e.g., wider, longer) than the first base portion 416 of the first cavity 403. In some implementations, a surface area of the first opening 414 of the first cavity 403 is greater (e.g., wider, longer) than a surface area of the first base portion 416 of the first cavity 403. In some implementations, a first adhesion layer 418 (e.g., oxide layer) is located on the first base portion 416. In some implementations, the first adhesion layer 418 is provided on the substrate 401 by using a plasma process that exposes the substrate 401 to oxygen and/or nitrogen. In some implementations, the adhesion layer 418 helps a component (e.g., a die) bond with the substrate 401. For example the adhesion layer 418 may bond directly with another adhesion layer (e.g., adhesion layer 304) of a die. In addition, the adhesion layer 418 may bond directly with the substrate of a die in the cavity. In some implementations, the adhesion layer (e.g., oxide layer) provides an adhesive that holds the die in place in the cavity.

In some implementations, the second cavity 405 has a second opening 424 and a second base portion 426. In the some implementations, the second opening 424 of the second cavity 405 is greater (e.g., wider, longer) than the second base portion 426 of the second cavity 405. In some implementations, a surface area of the second opening 424 of the second cavity 405 is greater (e.g., wider, longer) than a surface area of the second base portion 426 of the second cavity 205. In some implementations, a second adhesion layer 428 (e.g., oxide layer) is located on the second base portion 426. In some implementations, the second adhesion layer 428 is provided on the substrate 401 by using a plasma process that exposes the substrate 401 to oxygen and/or nitrogen. In some implementations, the adhesion layer 428 helps a component (e.g., a die) bond with the substrate 401. For example the adhesion layer 428 may bond directly with another adhesion layer (e.g., adhesion layer 304) of a die. In addition, the adhesion layer 418 may bond directly with the substrate of a die in the cavity. In some implementations, the adhesion layer (e.g., oxide layer) provides an adhesive that holds the die in place in the cavity.

In some implementations, the configuration of the first and second cavities 403 & 405 as described above, allow an integrated device (e.g., chip, die) to self-align in the cavities. In some implementations, this self-alignment of the integrated devices in the cavities substantially reduces the likelihood of misalignment of integrated devices in an integrated package.

Stage 2 of FIG. 4 illustrates an integrated device 430 (e.g., die, chip) being placed in the first cavity 403. As shown at stage 2, the integrated device 420 is not perfectly aligned with the base portion 416 of the first cavity 403 when the integrated device is initially placed in the first cavity 403. That is, the integrated device 402 is placed off-center of the first cavity 403 (e.g., off-center of the base portion 416 and/or off-center of the opening 414). However, the integrated package 430 is still placed within the first opening 414 of the first cavity 403. In some implementations, the angled edge 412 helps guide the integrated package 430 to the bottom of the cavity 403 and more towards the center of the cavity 403.

Stage 3 of FIG. 4 illustrates the integrated device 430 aligned with the base portion 416 of the first cavity 403. In some implementations, the integrated device 430 slides along the first edge 410 (e.g., first wall) or the second edge 412 (e.g., second wall) of the cavity 403. In some implementations, the sliding along the first edge 410 or the second edge 412 is how the integrated device 403 self-aligns in the cavity 403 and the substrate 401. That is, the second edge 412 helps guide the integrated device 403 towards the center of the cavity 403.

As shown in FIG. 4, the cavity 403 and the cavity 405 are each configured to align a die towards a center of the cavity when the die is initially placed off-center of the cavity. It should be noted that each die in its respective cavity is not necessarily perfectly centered within its respective cavity. Rather, the dies in the cavities are more centered then they would otherwise be if the cavities had vertical walls. Although only one integrated device (e.g., die) is shown placed in the substrate, it should be noted that two or more integrated devices may be placed in the substrate. It should also be noted that the adhesion layers (e.g., adhesion layer 418) are optional and are not necessary.

Exemplary Integrated Device that Includes Aligning Cavity and Cooling Enhancement

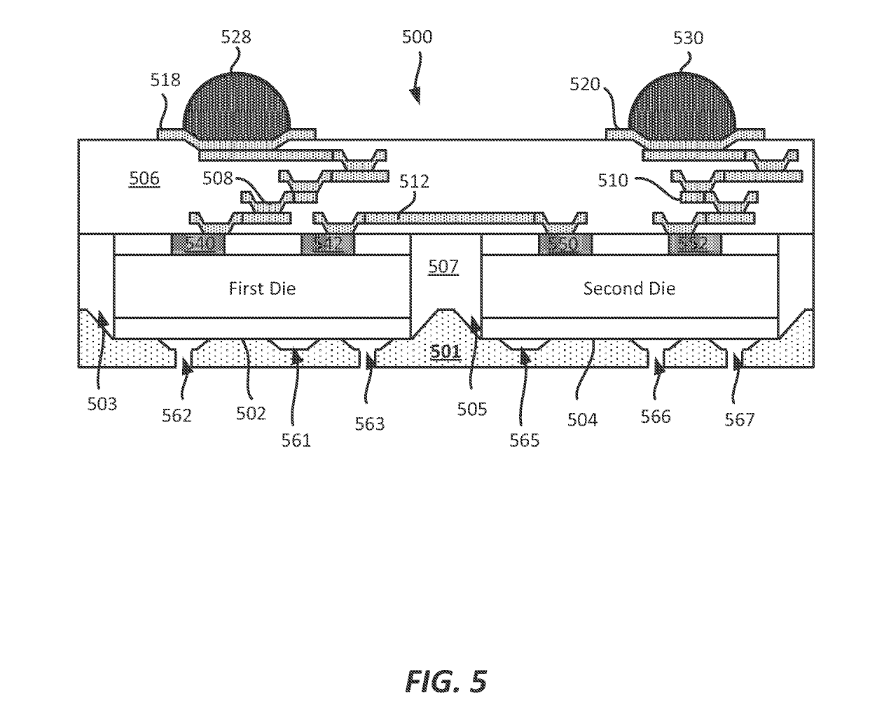

FIG. 5 conceptually illustrates an integrated device 500 that includes several dies, where the integrated device includes one or more aligning cavities (e.g., aligning trenches) and cooling enhancement. In some implementations, an aligning cavity is a cavity that may be configured to align a die towards a center of the cavity when the die is initially placed off-center of the cavity.

As shown in FIG. 5, the integrated device 500 (e.g., semiconductor device, integrated package) includes a substrate 501, a first integrated device 502 (e.g., first die, first chip), a second integrated device 504 (e.g., second die, second chip), a dielectric layer 506, a encapsulation layer 507 (e.g. mold), a first set of redistribution layers 508, a second set of redistribution layers 510, a third set of redistribution layers 512, a first under bump metallization (UBM) layer 518, a second under bump metallization (UBM) layer 520, a first solder ball 528, and a second solder ball 530.

Different implementations may use different materials for the substrate 501. For example, in some implementations, the substrate 501 may be one of at least silicon, glass, ceramic and/or dielectric. In some implementations, the dielectric layer 506, the first set of redistribution layers 508, the second set of redistribution layers 510, the third set of redistribution layers 512, the first under bump metallization (UBM) layer 518, and/or the second under bump metallization (UBM) layer 550 are part of and/or in a redistribution portion of the integrated device 500.

In some implementations, the dielectric layer 506 includes several dielectric layers. In some implementations, each of the first, second, and third sets of redistribution layers 508, 510, and 512 may include one or more interconnects (e.g., metal layers) and/or one or more vias. The first integrated device 502 includes a first interconnect 540 (e.g., first bump, first pillar) and a second interconnect 542 (e.g., second bump, second pillar). The second integrated device 504 includes a first interconnect 550 (e.g., first bump, first pillar) and a second interconnect 552 (e.g., second bump, second pillar). An example of an integrated device (e.g., device 502, device 504) is described with respect to FIG. 3.

The substrate 501 includes a first cavity 503 (e.g., first trench) and a second cavity 505 (e.g., second trench). The substrate 501 also includes cooling enhancements. In some implementations, the cooling enhancements are configured to dissipate heat away from one or more dies in the integrated device 500 (e.g., integrated package). FIG. 5 illustrates that the substrate 501 includes several cooling cavities. Specifically, FIG. 5 shows that the substrate 501 includes a first cooling cavity 561, a second cooling cavity 562, a third cooling cavity 563, a fourth cooling cavity 565, a fifth cooling cavity 566, and a sixth cooling cavity 567. In some implementations, the cooling cavities are configured to dissipate heat from the dies (e.g., integrated device 502 & 504) in the integrated device 500. In some implementations, the cooling cavities may partially traverse the substrate 501 and/or fully traverse the substrate 501.

As shown in FIG. 5, the first cooling cavity 561, the second cooling cavity 562, and the third cooling cavity 563 are coupled to the first cavity 503. The first cooling cavity 561 partially traverses the substrate 501. The second and third cooling cavities 562-563 completely traverse the substrate 501. In some implementations, the second cooling cavity 562 is an inlet opening, and the third cooling cavity 563 is an outlet opening. In some implementations, the first cooling cavity 561 is a cooling channel.

In some implementations, a pump may be coupled to the second and third cooling cavities 562-563. In some implementations, the pump may circulate a liquid (e.g., water) through the second cooling cavity 562 (e.g., inlet opening), which then flows through the first cooling cavity 562 (e.g., cooling channel), and out of the third cooling cavity 563 (e.g., outlet opening).

As further shown in FIG. 5, the fourth cooling cavity 565, the fifth cooling cavity 566, and the sixth cooling cavity 567 are coupled to the second cavity 505. The fourth cooling cavity 565 partially traverses the substrate 501. The fifth and sixth cooling cavities 566-567 completely traverse the substrate 501. In some implementations, the fifth cooling cavity 566 is an inlet opening, and the sixth cooling cavity 567 is an outlet opening. In some implementations, the fourth cooling cavity 565 is a cooling channel.

In some implementations, a pump may be coupled to the fifth and sixth cooling cavities 566-567. In some implementations, the pump may circulate a liquid (e.g., water) through the fifth cooling cavity 566 (e.g., inlet opening), which then flows through the fourth cooling cavity 565 (e.g., cooling channel), and out of the sixth cooling cavity 567 (e.g., outlet opening).

The first integrated device 502 is located in the first cavity 503. The second integrated device 504 is located in the second cavity 505. As shown in FIG. 5, in some implementations, the first and second cavities 503 & 505 have non-vertical edges (e.g., non-vertical walls). In some implementations, a non-vertical edge/wall is an edge or wall that is not perpendicular to a surface of the substrate (e.g., non-perpendicular to surface of the substrate that is not a side of the substrate, top surface, and/or bottom surface). In some implementations, the edge or wall of the first and second cavities 503 & 505 are at a non-perpendicular angle or non-vertical angle.

In some implementations, the first cavity 503 has an opening and a base portion. In the some implementations, the opening of the first cavity 503 is greater (e.g., wider, longer) than the base portion of the first cavity 503. In some implementations, a surface area of the opening of the first cavity 503 is greater (e.g., wider, longer) than a surface area of the base portion of the first cavity 503.

In some implementations, the second cavity 505 has an opening and a base portion. In the some implementations, the opening of the second cavity 505 is greater (e.g., wider, longer) than the base portion of the second cavity 505. In some implementations, a surface area of the opening of the second cavity 505 is greater (e.g., wider, longer) than a surface area of the base portion of the second cavity 505.

In some implementations, the configuration of the first and second cavities 503 & 505 as described above, allows an integrated device (e.g., chip, die) to self-align in the cavities. In some implementations, this self-alignment of the integrated devices in the cavities substantially reduces the likelihood of misalignment of integrated devices in an integrated package.

As a result of this self-alignment of the dies in an integrated package, connections in the integrated device 500 are properly coupled. As shown in FIG. 5, the first interconnect 540 of the first integrated device 502 is coupled to the first set of redistribution layers 508. The second interconnect 542 of the first integrated device 502 is coupled to the third set of redistribution layers 512. FIG. 5 also shows that the first interconnect 550 of the second integrated device 504 is coupled to the third set of redistribution layers 512. FIG. 5 further illustrates that the second set of redistribution layers 510 is coupled to the second interconnect 552 of the second integrated device 504.

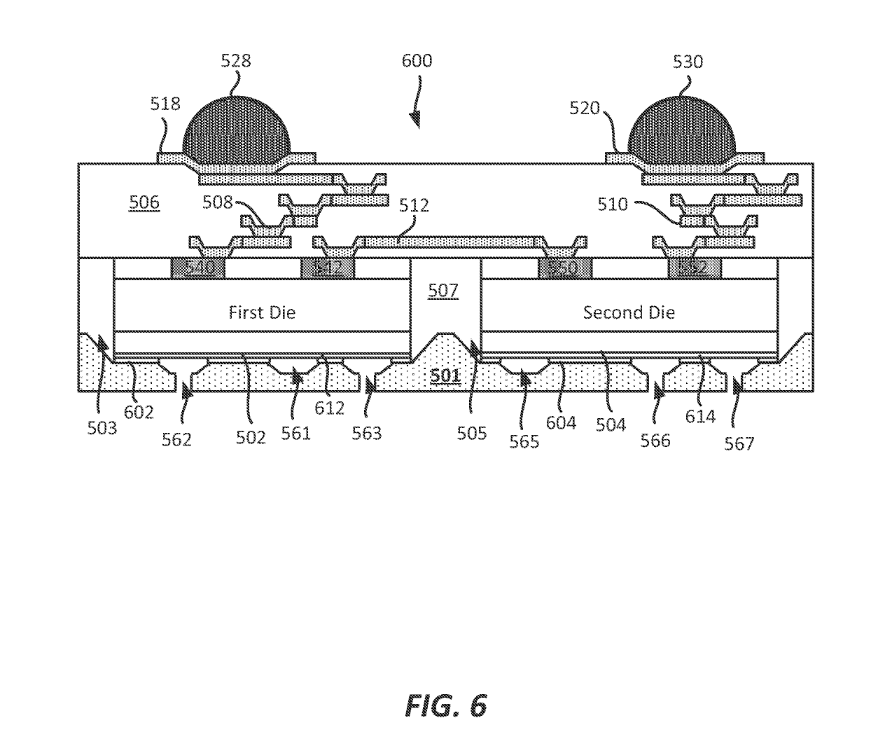

In some implementations, one or more adhesion layers (e.g., oxide layers) may be use to bond a die to a substrate. FIG. 6 illustrates a configuration of an integrated device, where one or more adhesion layers are use to bond a die to a substrate. FIG. 6 is similar to FIG. 5, except that FIG. 6 illustrates an integrated device 600 that includes several dies (e.g., dies 502, 504) that are coupled to the substrate 501 through at least one adhesion layer (e.g., oxide layer).

Specifically, FIG. 6 illustrates a first adhesion layer 602 (e.g., oxide layer) and a second adhesion layer 604 (e.g., oxide layer) on the substrate. The first die 502 includes a third adhesion layer 612, and the second die 504 includes a fourth adhesion layer 614. In some implementations, the first adhesion layer 602 and the third adhesion layer 612 provide an adhesion layer that couples (e.g., bonds) the first die 502 to the substrate 501. In some implementations, the first adhesion layer 602 and the third adhesion layer 612 is a single adhesion layer. In some implementations, an adhesion layer may be initially provided on the substrate 501 and/or the first die 502. In some implementations, the second adhesion layer 604 and the fourth adhesion layer 614 provide an adhesion layer that couples (e.g., bonds) the second die 504 to the substrate 501. In some implementations, the second adhesion layer 604 and the fourth adhesion layer 614 is a single adhesion layer. In some implementations, an adhesion layer may be initially provided on the substrate 501 and/or the second die 504.

In some implementations, the cavities may be filled with a thermally conductive material. In such instances, the cavities filled with the thermally conductive material may be configured to operate as a heat sink.

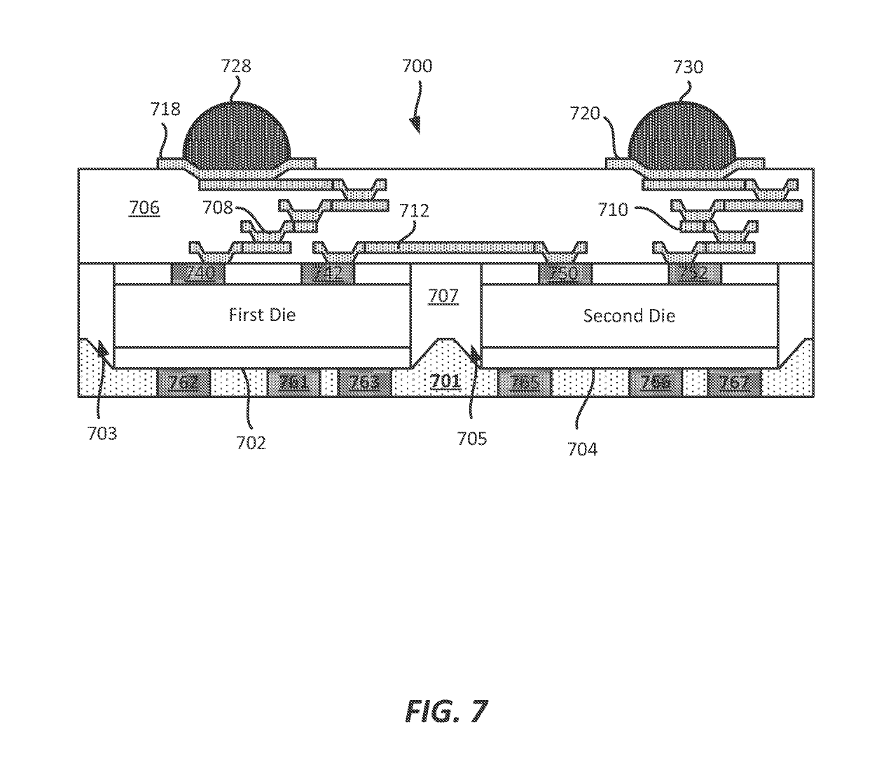

FIG. 7 conceptually illustrates an integrated device 700 that includes several dies, where the integrated device includes one or more aligning cavities (e.g., aligning trenches) and cooling enhancement (e.g., heat sink). In some implementations, an aligning cavity is a cavity that may be configured to align a die towards a center of the cavity when the die is initially placed off-center of the cavity.

As shown in FIG. 7, the integrated device 700 (e.g., semiconductor device, integrated package) includes a substrate 701, a first integrated device 702 (e.g., first die, first chip), a second integrated device 704 (e.g., second die, second chip), a dielectric layer 706, a encapsulation layer 707 (e.g., mold), a first set of redistribution layers 708, a second set of redistribution layers 710, a third set of redistribution layers 712, a first under bump metallization (UBM) layer 718, a second under bump metallization (UBM) layer 720, a first solder ball 728, and a second solder ball 730.

Different implementations may use different materials for the substrate 701. For example, in some implementations, the substrate 701 may be one of at least silicon, glass, ceramic and/or dielectric. In some implementations, the dielectric layer 706, the first set of redistribution layers 708, the second set of redistribution layers 710, the third set of redistribution layers 712, the first under bump metallization (UBM) layer 718, and/or the second under bump metallization (UBM) layer 720 are part of and/or in a redistribution portion of the integrated device 700.

In some implementations, the dielectric layer 706 includes several dielectric layers. In some implementations, each of the first, second, and third sets of redistribution layers 708, 710, and 712 may include one or more interconnects (e.g., metal layers) and/or one or more vias. The first integrated device 702 includes a first interconnect 740 (e.g., first bump, first pillar) and a second interconnect 742 (e.g., second bump, second pillar). The second integrated device 704 includes a first interconnect 750 (e.g., first bump, first pillar) and a second interconnect 752 (e.g., second bump, second pillar). An example of an integrated device (e.g., device 702, device 704) is described with respect to FIG. 3.

The substrate 701 includes a first cavity 703 (e.g., first trench) and a second cavity 705 (e.g., second trench). The substrate 701 also includes cooling enhancements. In some implementations, the cooling enhancements are configured to dissipate heat away from one or more dies in the integrated device 700 (e.g., integrated package). Specifically, FIG. 7 illustrates that the substrate 701 includes a first heat sink 761, and a second heat sink 762, a third heat sink 763, a fourth heat sink 765, a fifth heat sink 766, and a sixth heat sink 767. In some implementations, heat sinks (e.g., heat sinks 761-763, 765-767) completely traverse the substrate 701. In some implementations, the first, second, and third heat sinks 761-763 are coupled to the first integrated device 702. In some implementations, the fourth, fifth, and sixth heat sinks 765-767 are coupled to the second integrated device 704. In some implementations, the heat sinks 761-763 and 765-767 are configured to dissipate heat from the dies (e.g., integrated device 702 & 704) in the integrated device 700.

The first integrated device 702 is located in the first cavity 703. The second integrated device 704 is located in the second cavity 705. As shown in FIG. 7, in some implementations, the first and second cavities 703 & 705 have non-vertical edges (e.g., non-vertical walls). In some implementations, a non-vertical edge/wall is an edge or wall that is not perpendicular to a surface of the substrate (e.g., non-perpendicular to surface of the substrate that is not a side of the substrate, top surface, and/or bottom surface). In some implementations, the edge or wall of the first and second cavities 703 & 705 are at a non-perpendicular angle or non-vertical angle.

In some implementations, the first cavity 703 has an opening and a base portion. In the some implementations, the opening of the first cavity 703 is greater (e.g., wider, longer) than the base portion of the first cavity 703. In some implementations, a surface area of the opening of the first cavity 703 is greater (e.g., wider, longer) than a surface area of the base portion of the first cavity 703.

In some implementations, the second cavity 705 has an opening and a base portion. In the some implementations, the opening of the second cavity 705 is greater (e.g., wider, longer) than the base portion of the second cavity 705. In some implementations, a surface area of the opening of the second cavity 705 is greater (e.g., wider, longer) than a surface area of the base portion of the second cavity 705.

In some implementations, the configuration of the first and second cavities 703 & 705 as described above, allows an integrated device (e.g., chip, die) to self-align in the cavities. In some implementations, this self-alignment of the integrated devices in the cavities substantially reduces the likelihood of misalignment of integrated devices in an integrated package.

As a result of this self-alignment of the dies in an integrated package, connections in the integrated device 700 are properly coupled. As shown in FIG. 7, the first interconnect 740 of the first integrated device 702 is coupled to the first set of redistribution layers 708. The second interconnect 742 of the first integrated device 702 is coupled to the third set of redistribution layers 712. FIG. 7 also shows that the first interconnect 750 of the second integrated device 704 is coupled to the third set of redistribution layers 712. FIG. 7 further illustrates that the second set of redistribution layers 710 is coupled to the second interconnect 752 of the second integrated device 704.

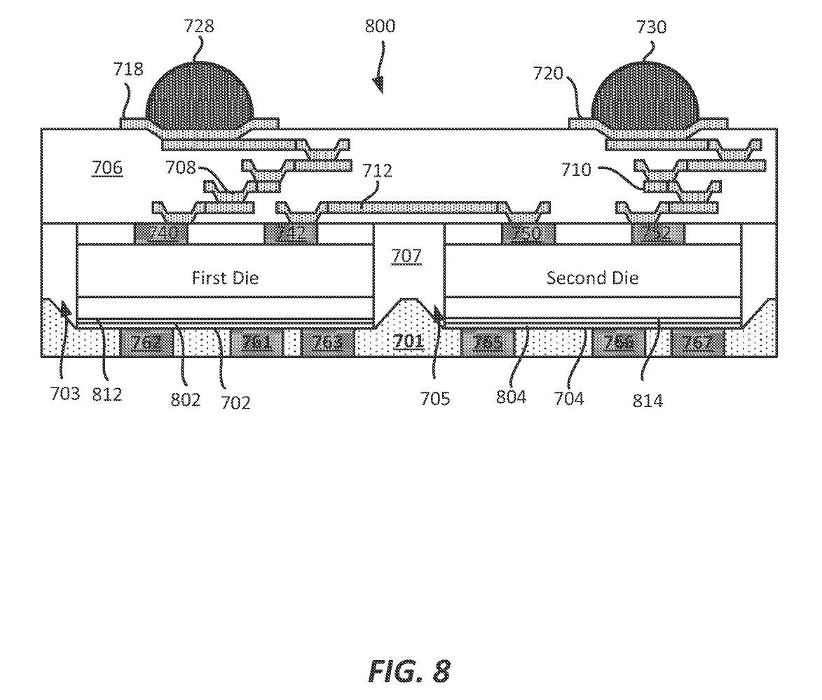

In some implementations, one or more adhesion layers (e.g., oxide layers) may be use to bond a die to a substrate. FIG. 8 illustrates a configuration of an integrated device, where one or more adhesion layers (e.g., oxide layers) are use to bond a die to a substrate. FIG. 8 is similar to FIG. 7, except that FIG. 8 illustrates an integrated device 800 that includes several dies (e.g., dies 702, 704) that are coupled to the substrate 701 through at least one adhesion layer.

Specifically, FIG. 8 illustrates a first adhesion layer 802 (e.g. oxide layer) and a second adhesion layer 804 (e.g., oxide layer) on the substrate. The first die 702 includes a third adhesion layer 812, and the second die 704 includes a fourth adhesion layer 814. In some implementations, the first adhesion layer 802 and the third adhesion layer 812 provide an adhesion layer that couples (e.g., bonds) the first die 702 to the substrate 701. In some implementations, the first adhesion layer 802 and the third adhesion layer 812 is a single adhesion layer. In some implementations, an adhesion layer may be initially provided on the substrate 701 and/or the first die 702. In some implementations, the second adhesion layer 804 and the fourth adhesion layer 814 provide an adhesion layer that couples (e.g., bonds) the second die 704 to the substrate 701. In some implementations, the second adhesion layer 804 and the fourth adhesion layer 814 is a single adhesion layer. In some implementations, an adhesion layer may be initially provided on the substrate 701 and/or the second die 704.

It should be noted that in some implementations, an integrated device may have a combination of the cooling cavities and/or heat sinks. It should also be noted that the shapes of the cooling cavities and/or heat sinks is merely exemplary. Different implementations may use different shapes for the cooling cavities and/or heat sinks.

Having described various integrated devices, a sequence for providing/manufacturing an integrated device will now be described below.

Exemplary Sequence for Providing/Manufacturing an Integrated Device that Includes an Aligning Cavity

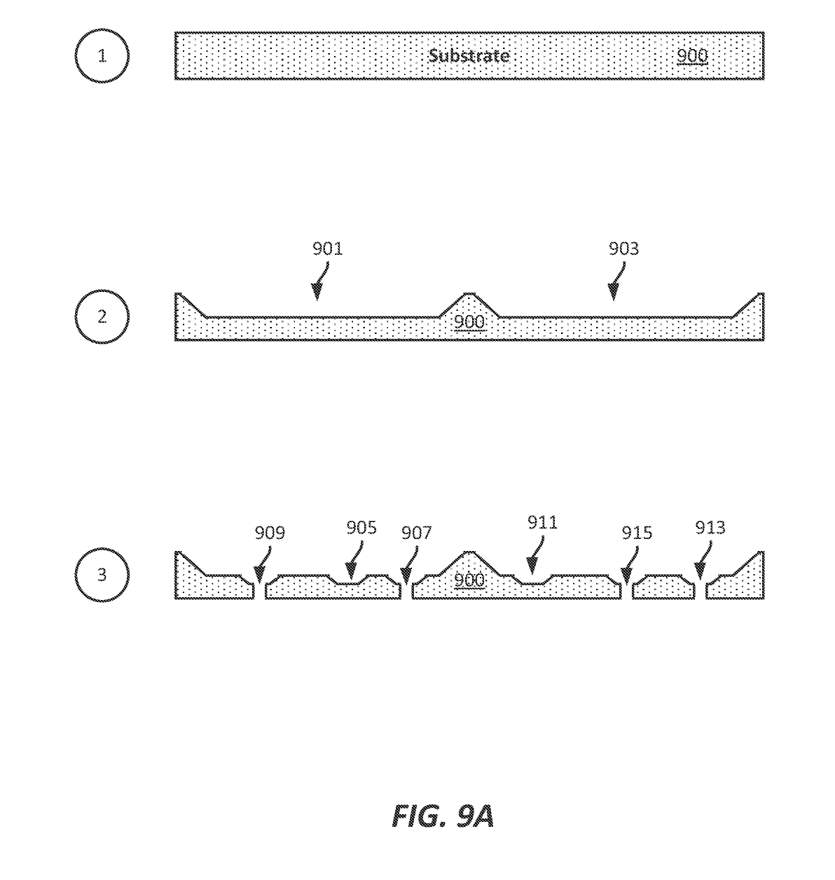

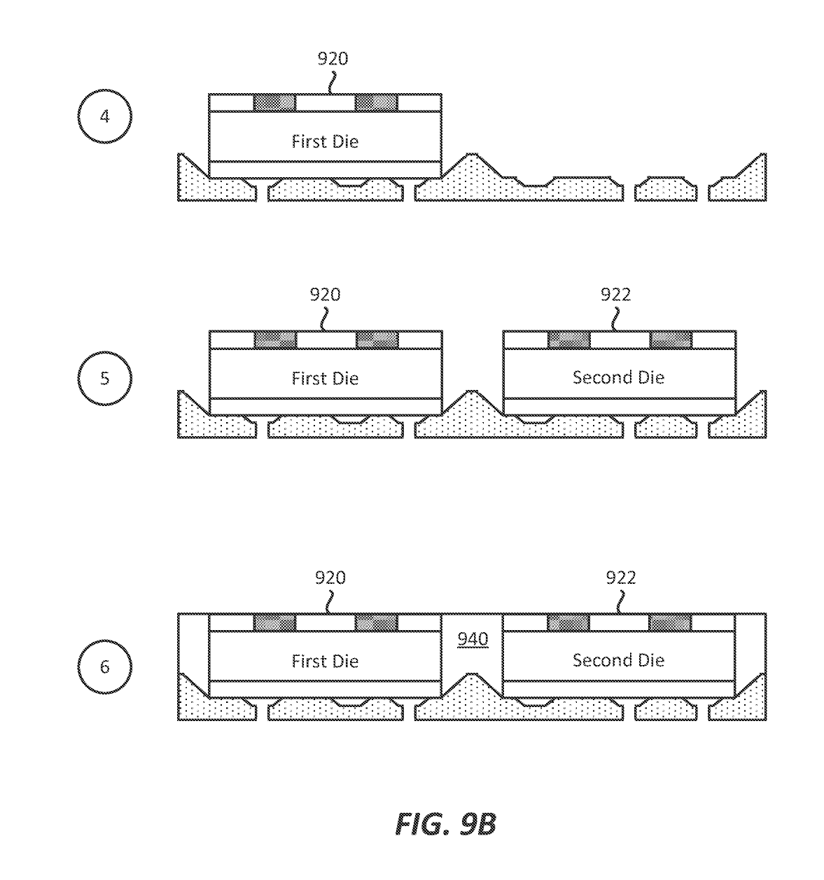

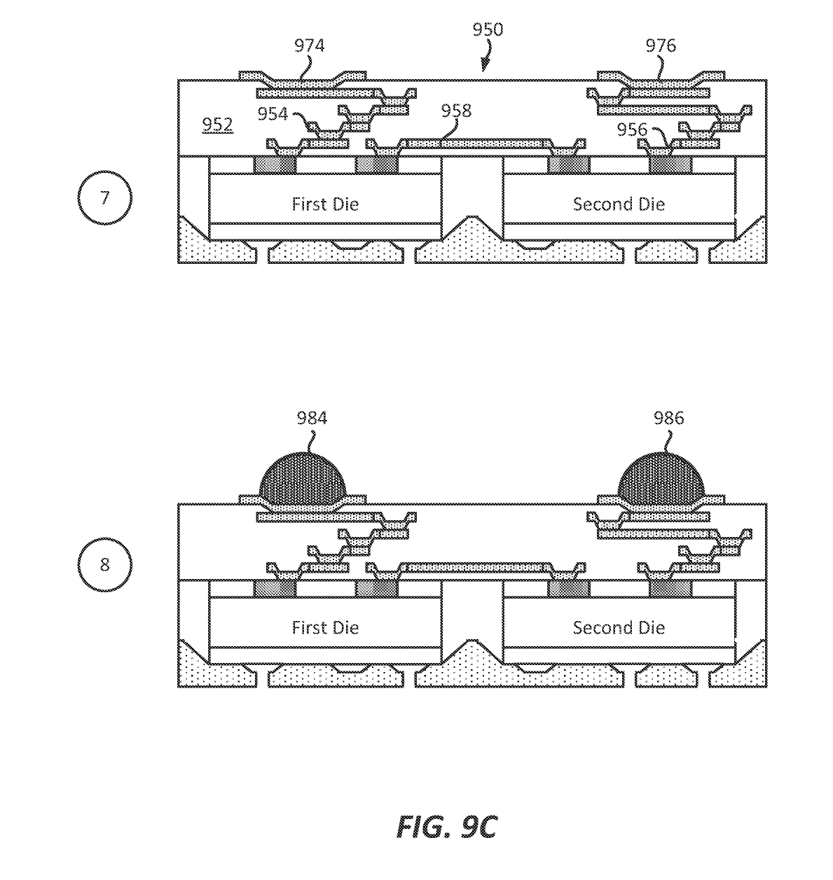

FIGS. 9A-9C illustrate an exemplary sequence for providing an integrated device that aligning cavities and/or cooling enhancements. In some implementations, the sequence of FIGS. 9A-9C may be used to provide/manufacture the integrated device of FIGS. 2, 5 and/or 6, and/or other integrated devices described in the present disclose. It should also be noted that the sequence of FIGS. 9A-9C may be used to provide/manufacture integrated devices that also include circuit elements. It should further be noted that the sequence of FIGS. 9A-9C may combine one or more stages in order to simplify and/or clarify the sequence for providing an integrated device that includes aligning cavities and/or cooling enhancements.

As shown in stage 1 of FIG. 9A, a substrate (e.g., substrate 900) is provided. In some implementations, the substrate 900 is a wafer. Different implementations may use different materials for the substrate (e.g., silicon substrate, glass substrate, ceramic substrate).

At stage 2, a first cavity 901 (e.g., first trench) and a second cavity 903 (e.g., second trench) are provided. Different implementations may provide the cavities in the substrate differently. In some implementations, a laser may be used to provide the cavity. In some implementations, an etching (e.g., chemical, mechanical) process may be used to provide the cavity.

As shown at stage 2, the first and second cavities 901 & 903 have non-vertical edges (e.g., non-vertical walls). In some implementations, a non-vertical edge/wall is an edge or wall that is not perpendicular to a surface of the substrate (e.g., non-perpendicular to surface of the substrate that is not a side of the substrate, top surface, and/or bottom surface). In some implementations, the edge or wall of the first and second cavities 901 & 903 are at a non-perpendicular angle or non-vertical angle. In some implementations, a cavity may be configured to align a die towards a center of the cavity when the die is initially placed off-center of the cavity.

In some implementations, the first cavity 901 has an opening and a base portion. In the some implementations, the opening of the first cavity 901 is greater (e.g., wider, longer) than the base portion of the first cavity 901. In some implementations, a surface area of the opening of the first cavity 901 is greater (e.g., wider, longer) than a surface area of the base portion of the first cavity 901.

In some implementations, the second cavity 903 has an opening and a base portion. In the some implementations, the opening of the second cavity 903 is greater (e.g., wider, longer) than the base portion of the second cavity 903. In some implementations, a surface area of the opening of the second cavity 903 is greater (e.g., wider, longer) than a surface area of the base portion of the second cavity 903.

In some implementations, the configuration of the first and second cavities 901 & 903 as described above, allows an integrated device (e.g., chip, die) to self-align in the cavities. In some implementations, this self-alignment of the integrated devices in the cavities substantially reduces the likelihood of misalignment of integrated devices in an integrated package. In some implementations, an adhesion layer (e.g., oxide layer) may be provided at stage 2. In such instances, a plasma process that exposes part of the substrate to oxygen and/or nitrogen may be use to provide an adhesion layer (e.g., oxide layer).

At stage 3, additional cavities are optionally provided. As shown at stage 3, a first cavity 905, a second cavity 907, a third cavity 909, a fourth cavity 911, a fifth cavity 913, and a sixth cavity 915 are provided in the substrate 900. Different implementations may provide the cavities in the substrate differently. In some implementations, a laser may be used to provide the cavity. In some implementations, an etching (e.g., chemical, mechanical) process may be used to provide the cavity.

The first cavity 905 and the fourth cavity 911 partially traverse the substrate 900. The second cavity 907, the third cavity 909, the fifth cavity 913, and the sixth cavity 915 completely traverse the substrate 900.

As shown in FIG. 9B, at stage 4, a first integrated device 920 (e.g., first die) is provided in the first cavity 901 of the substrate 900. Different implementations may use different integrated devices (e.g., dies). An example of an integrated device (e.g., die) that may be use is integrated device 300, as shown and described in FIG. 3.

At stage 5, a second integrated device 922 (e.g., second die) is provided in the second cavity 903 of the substrate 900. Different implementations may use different integrated devices (e.g., dies).

At stage 6, an encapsulation layer 940 (e.g., mold) is provided on the substrate 900 and partially encapsulates the first and second integrated devices 920 and 922. In some implementations, portions of the first and second integrated device 920 and 922 are left exposed (e.g., bump area of the integrated devices are left exposed or free of the encapsulation layer 940).

As shown in FIG. 9C, at stage 7, a redistribution portion 950 is provided on the first integrated device 920, the second integrated device 922, and/or the encapsulation layer 940. In some implementations, the redistribution portion 950 includes a dielectric layer 952, a first set of redistribution layers 954, a second set of redistribution layers 956, a third set of redistribution layers 958, a first under bump metallization (UBM) layer 974, and/or the second under bump metallization (UBM) layer 976. In some implementations, the dielectric layer 952 may includes several dielectric layers. It should be noted that in some implementations, a first dielectric may be provided followed by a first redistribution layer, a second dielectric layer, a second redistribution layer, and so on and so forth.

At stage 8, at least one solder ball is provided on the UBM layer. Specifically, a first solder ball 984 is coupled to the first UBM layer 974, and a second solder ball 986 is coupled to the second UBM layer 976.

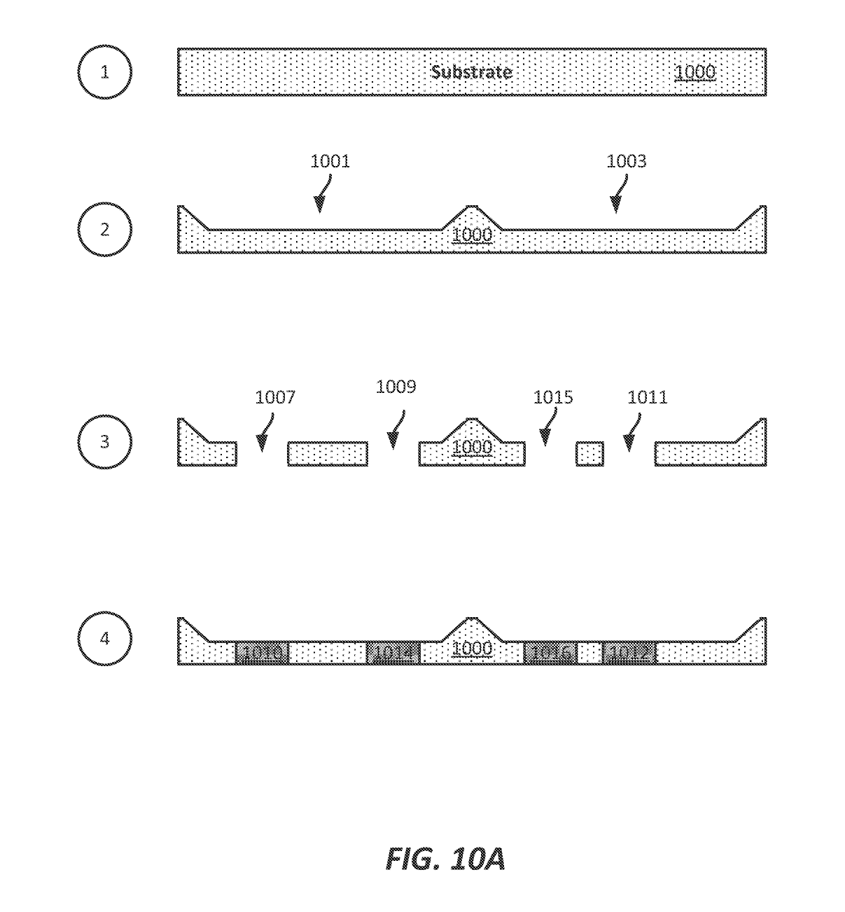

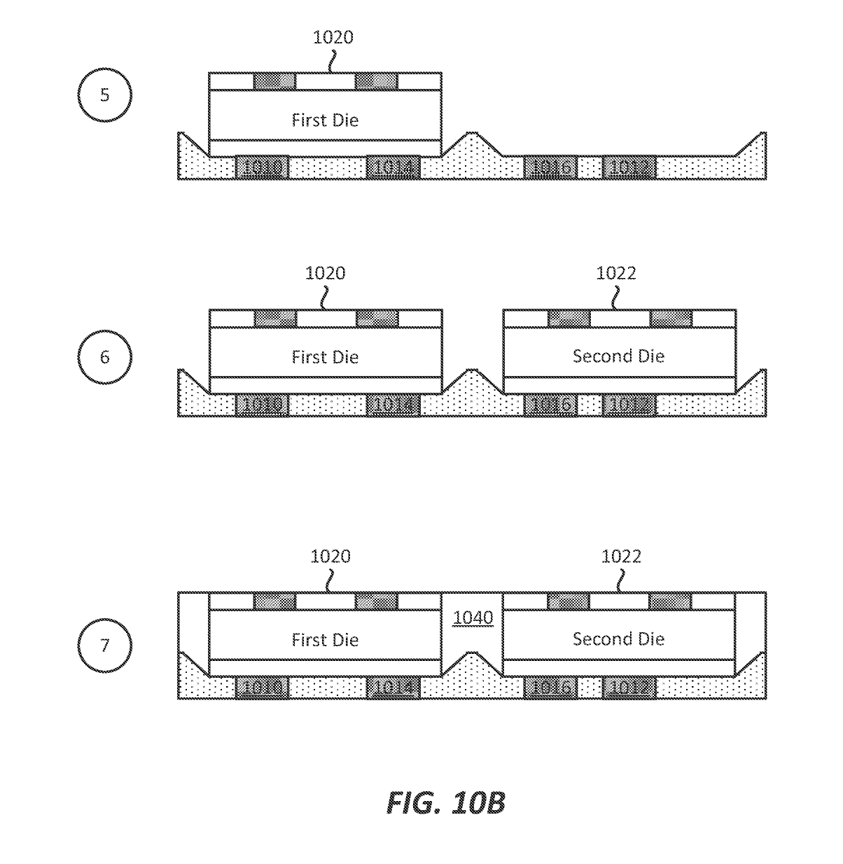

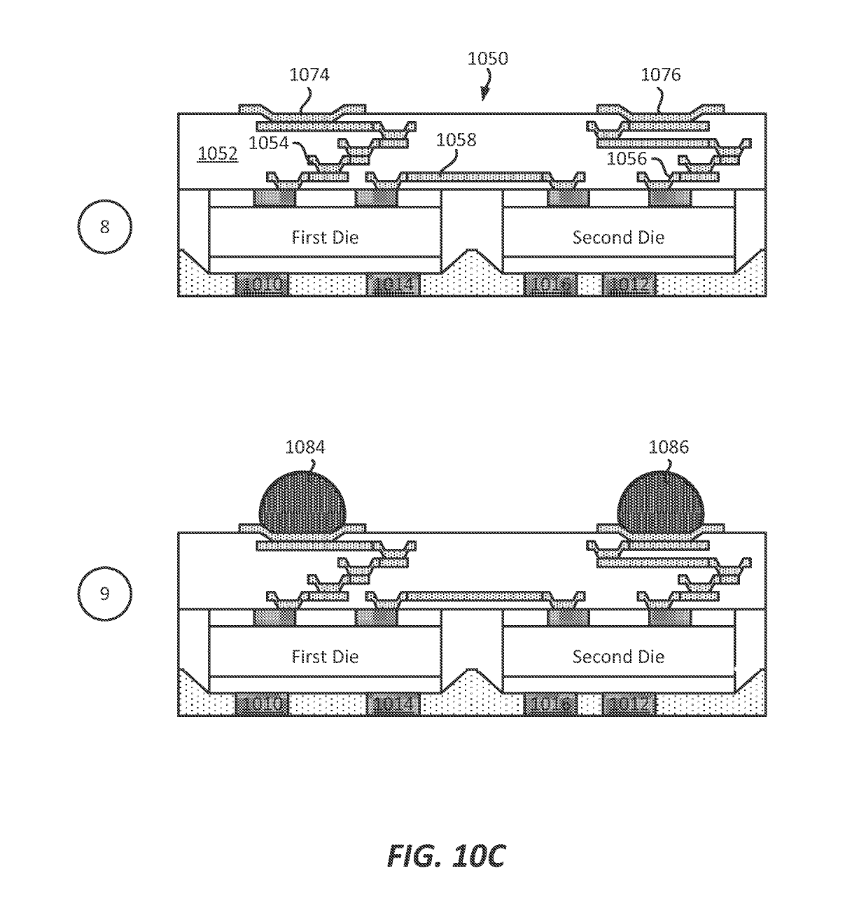

In some implementations, an integrated device may include a heat sink. FIGS. 10A-10C illustrate an exemplary sequence for providing an integrated device that aligning cavities and/or cooling enhancements (e.g., heat sink). In some implementations, the sequence of FIGS. 10A-10C may be used to provide/manufacture the integrated device of FIGS. 2, 7 and/or 8, and/or other integrated devices described in the present disclose. It should also be noted that the sequence of FIGS. 10A-10C may be used to provide/manufacture integrated devices that also include circuit elements. It should further be noted that the sequence of FIGS. 10A-10C may combine one or more stages in order to simplify and/or clarify the sequence for providing an integrated device that includes aligning cavities and/or cooling enhancements.

As shown in stage 1 of FIG. 10A, a substrate (e.g., substrate 1000) is provided. In some implementations, the substrate 900 is a wafer. Different implementations may use different materials for the substrate (e.g., silicon substrate, glass substrate, ceramic substrate).

At stage 2, a first cavity 1001 (e.g., first trench) and a second cavity 1003 (e.g., second trench) are provided. Different implementations may provide the cavities in the substrate differently. In some implementations, a laser may be used to provide the cavity. In some implementations, an etching (e.g., chemical, mechanical) process may be used to provide the cavity.

As shown at stage 2, the first and second cavities 1001 & 1003 have non-vertical edges (e.g., non-vertical walls). In some implementations, a non-vertical edge/wall is an edge or wall that is not perpendicular to a surface of the substrate (e.g., non-perpendicular to surface of the substrate that is not a side of the substrate, top surface, and/or bottom surface). In some implementations, the edge or wall of the first and second cavities 1001 & 1003 are at a non-perpendicular angle or non-vertical angle. In some implementations, a cavity may be configured to align a die towards a center of the cavity when the die is initially placed off-center of the cavity.

In some implementations, the first cavity 1001 has an opening and a base portion. In the some implementations, the opening of the first cavity 1001 is greater (e.g., wider, longer) than the base portion of the first cavity 1001. In some implementations, a surface area of the opening of the first cavity 1001 is greater (e.g., wider, longer) than a surface area of the base portion of the first cavity 1001.

In some implementations, the second cavity 1003 has an opening and a base portion. In the some implementations, the opening of the second cavity 1003 is greater (e.g., wider, longer) than the base portion of the second cavity 1003. In some implementations, a surface area of the opening of the second cavity 1003 is greater (e.g., wider, longer) than a surface area of the base portion of the second cavity 1003.

In some implementations, the configuration of the first and second cavities 1001 & 1003 as described above, allows an integrated device (e.g., chip, die) to self-align in the cavities. In some implementations, this self-alignment of the integrated devices in the cavities substantially reduces the likelihood of misalignment of integrated devices in an integrated package. In some implementations, an adhesion layer (e.g., oxide layer) may be provided at stage 2. In such instances, a plasma process that exposes part of the substrate to oxygen and/or nitrogen may be use to provide an adhesion layer (e.g., oxide layer).

At stage 3, additional cavities are provided. As shown at stage 3, a first cavity 1007, a second cavity 1009, a third cavity 1011, and a fourth cavity 1015 are provided in the substrate 1000. Different implementations may provide the cavities in the substrate differently. In some implementations, a laser may be used to provide the cavity. In some implementations, an etching (e.g., chemical, mechanical) process may be used to provide the cavity.

The first cavity 1007, the second cavity 1009, the third cavity 1011, and the fourth cavity 1015 completely traverse the substrate 1000.

At stage 4, at least some of the cavities are filled with a thermally conductive material. Specifically, the first cavity 1007 is filled with a thermally conductive material to produce a first heat sink 1010, the second cavity 1009 is filled with a thermally conductive material to produce a second heat sink 1014. In addition, the third cavity 1011 is filled with a thermally conductive material to produce a third heat sink 1012, the fourth cavity 1015 is filled with a thermally conductive material to produce a second heat sink 1016. In some implementations, the thermally conductive material is a metal.

In some implementations, In some implementations, an adhesion layer (e.g., oxide layer) may be provided at stage 4. In such instances, a plasma process that exposes part of the substrate to oxygen and/or nitrogen may be use to provide an adhesive layer (e.g., oxide layer).

As shown in FIG. 10B, at stage 5, a first integrated device 1020 (e.g., first die) is provided in the first cavity 1001 of the substrate 1000. Different implementations may use different integrated devices (e.g., dies). An example of an integrated device (e.g., die) that may be use is integrated device 300, as shown and described in FIG. 3.

At stage 6, a second integrated device 1022 (e.g., second die) is provided in the second cavity 1003 of the substrate 1000. Different implementations may use different integrated devices (e.g., dies).

At stage 7, an encapsulation layer 1040 (e.g., mold) is provided on the substrate 1000 and partially encapsulates the first and second integrated devices 1020 and 1022. In some implementations, portions of the first and second integrated device 1020 and 1022 are left exposed (e.g., bump area of the integrated devices are left exposed or free of the encapsulation layer 1040).

As shown in FIG. 10C, at stage 8, a redistribution portion 1050 is provided on the first integrated device 1020, the second integrated device 1022, and/or the encapsulation layer 1040. In some implementations, the redistribution portion 1050 includes a dielectric layer 1052, a first set of redistribution layers 1054, a second set of redistribution layers 1056, a third set of redistribution layers 1058, a first under bump metallization (UBM) layer 1074, and/or the second under bump metallization (UBM) layer 1076. In some implementations, the dielectric layer 1052 may includes several dielectric layers. It should be noted that in some implementations, a first dielectric may be provided followed by a first redistribution layer, a second dielectric layer, a second redistribution layer, and so on and so forth.

At stage 9, at least one solder ball is provided on the UBM layer. Specifically, a first solder ball 1084 is coupled to the first UBM layer 1074, and a second solder ball 1086 is coupled to the second UBM layer 1076.

Having described a sequence for providing/manufacturing an integrated device (e.g., semiconductor device), a method for providing/manufacturing an integrated device (e.g., semiconductor device) will now be described below.

Having described a sequence for providing/manufacturing an integrated device (e.g., semiconductor device), a method for providing/manufacturing an integrated device (e.g., semiconductor device) will now be described below.

Exemplary Method for Providing/Manufacturing an Integrated Device that Includes an Aligning Cavity and/or Cooling Enhancements

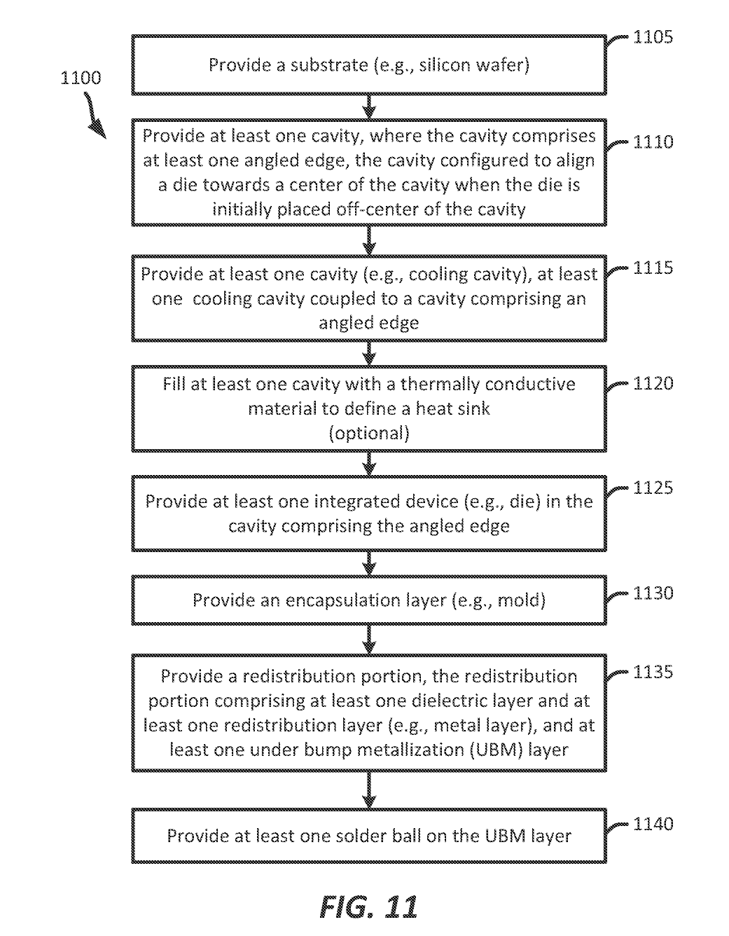

FIG. 11 illustrates an exemplary method for providing an integrated device (e.g., die package) that includes an aligning cavity and/or a cooling enhancement. In some implementations, the method of FIG. 11 may be used to provide/manufacture the integrated device of FIGS. 2, 5, 6, 7, and/or 8, and/or other integrated devices (e.g., die package) described in the present disclose.

The method provides (at 1105) a substrate (e.g., substrate 900). In some implementations, the substrate 900 is a wafer. Different implementations may use different materials for the substrate (e.g., silicon substrate, glass substrate, ceramic substrate).

The method then provides (at 1110) at least one cavity, where the cavity includes an angled edge, and the cavity is configured to hold an integrated device (e.g., die). For example, the method may provide (at 1110) a first cavity 901 (e.g., first trench) and a second cavity 903 (e.g., second trench) in the substrate 900. Different implementations may provide the cavities in the substrate differently. In some implementations, a laser may be used to provide the cavity. In some implementations, an etching (e.g., chemical, mechanical) process may be used to provide the cavity.

In some implementations, the cavities (e.g., the first and second cavities 901 & 903) have non-vertical edges (e.g., non-vertical walls). In some implementations, a non-vertical edge/wall is an edge or wall that is not perpendicular to a surface of the substrate (e.g., non-perpendicular to surface of the substrate that is not a side of the substrate, top surface, and/or bottom surface). In some implementations, the edge or wall of the cavities (e.g., the first and second cavities 901 & 903) are at a non-perpendicular angle of the surface of the substrate or non-vertical angle. In some implementations, a cavity may be configured to align a die towards a center of the cavity when the die is initially placed off-center of the cavity.

In some implementations, each of the cavities (e.g., first cavity 901) has an opening and a base portion. In the some implementations, the opening of a cavity (e.g., first cavity 901) is greater (e.g., wider, longer) than the base portion of the cavity (e.g., first cavity 901). In some implementations, a surface area of the opening of a cavity is greater (e.g., wider, longer) than a surface area of the base portion of the cavity.

In some implementations, the configuration of the cavities (e.g., trenches) as described above, allows an integrated device (e.g., chip, die) to self-align in the cavities. In some implementations, this self-alignment of the integrated devices in the cavities substantially reduces the likelihood of misalignment of integrated devices in an integrated package.

The method further optionally provides (at 1115) at least one cooling cavity (e.g., a first cavity 905, a second cavity 907). In some implementations, the cooling cavity is coupled to a cavity configured to hold an integrated device. Different implementations may provide the cavities in the substrate differently. In some implementations, a laser may be used to provide the cavity. In some implementations, an etching (e.g., chemical, mechanical) process may be used to provide the cavity. The cavities may partially traverse or completely traverse the substrate in some implementations.

The method then optionally fills (at 1120) at least one cavity with a thermally conductive material. In some implementations, filling a cavity with a thermally conductive material produces a heat sink (e.g., heat sink 1010). In some implementations, the heat sink may be configured to dissipate heat away from a die in an integrated package.

The method further provides (at 1125) at least one integrated device (e.g., die, first integrated device 920) in a cavity (e.g., first cavity 901) of the substrate. Different implementations may use different integrated devices (e.g., dies). An example of an integrated device (e.g., die) that may be used is integrated device 300, as shown and described in FIG. 3.

The method provides (at 1130) an encapsulation layer (e.g., mold 940) on the substrate. In some implementations, the encapsulation layer at least partially encapsulates dies (e.g., first and second integrated devices 920 and 922). In some implementations, portions of the dies are left exposed (e.g., bump area of the integrated devices are left exposed or free of the encapsulation layer).

The method further provides (at 1135) a redistribution portion (e.g., redistribution portion 950) on the die(s) and/or encapsulation layer (e.g., mold). In some implementations, the redistribution portion includes a dielectric layer, one or more redistribution layers, and/or one or more second under bump metallization (UBM) layers. In some implementations, the dielectric layer may include several dielectric layers. It should be noted that in some implementations, a first dielectric may be provided followed by a first redistribution layer, a second dielectric layer, a second redistribution layer, and so on and so forth.

The method also provides (at 1140) at least one solder ball. In some implementations, providing the solder ball includes coupling a solder ball to a UBM layer. For example, providing a solder ball may include coupling a first solder ball 984 to a first UBM layer 974. In some implementations, the UBM layers are optional.

### Exemplary Electronic Devices

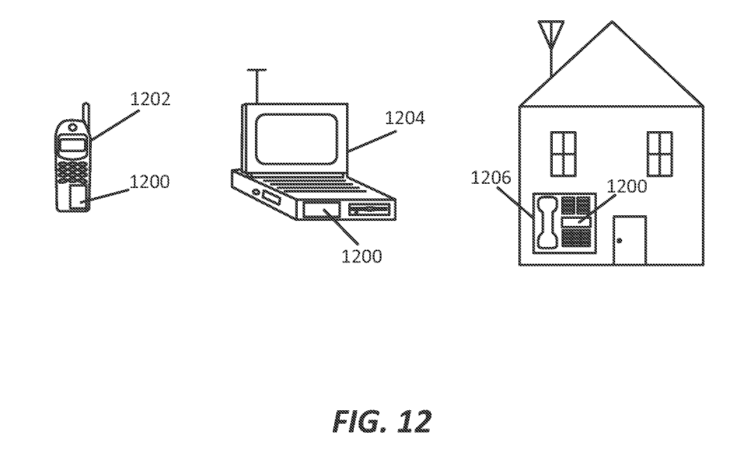

FIG. 12 illustrates various electronic devices that may be integrated with any of the aforementioned semiconductor device, integrated circuit, die, interposer or package. For example, a mobile telephone 1202, a laptop computer 1204, and a fixed location terminal 1206 may include an integrated circuit (IC) 1200 as described herein. The IC 1200 may be, for example, any of the integrated circuits, dice or packages described herein. The devices 1202, 1204, 1206 illustrated in FIG. 12 are merely exemplary. Other electronic devices may also feature the IC 1200 including, but not limited to, mobile devices, hand-held personal communication systems (PCS) units, portable data units such as personal digital assistants, GPS enabled devices, navigation devices, set top boxes, music players, video players, entertainment units, fixed location data units such as meter reading equipment, communications devices, smartphones, tablet computers or any other device that stores or retrieves data or computer instructions, or any combination thereof.

One or more of the components, steps, features, and/or functions illustrated in FIGS. 2, 3, 4, 5, 6, 7, 8, 9A-9C, 10A-10C, 11 and/or 12 may be rearranged and/or combined into a single component, step, feature or function or embodied in several components, steps, or functions. Additional elements, components, steps, and/or functions may also be added without departing from the invention. It should also be noted that FIGS. 2, 3, 4, 5, 6, 7, 8, 9A-9C, 10A-10C, 11 and/or 12 and its corresponding description in the present disclosure is not limited to dies and/or ICs. In some implementations, 2, 3, 4, 5, 6, 7, 8, 9A-9C, 10A-10C, 11 and/or 12 and its corresponding description may be used to manufacture, create, provide, and/or produce integrated devices. In some implementations, an integrated device may include a die, a die package, an integrated package, an integrated circuit (IC), a wafer, and/or a semiconductor device.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other.

Throughout the application, the use of a mold is described. It should be noted that the mold described in the present disclosure may be replace with other types of encapsulation layers and/or encapsulation materials. That is, a mold is one type of encapsulation layer/material that may be used to encapsulation an integrated device and/or die. In some implementations, the mold described in the present disclosure may be replaced with other encapsulation layers and/or materials, such as a epoxy and/or polymer fill.

Also, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the invention described herein can be implemented in different systems without departing from the invention. It should be noted that the foregoing aspects of the disclosure are merely examples and are not to be construed as limiting the invention. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An integrated device comprising:
a substrate comprising a first cavity, wherein the first cavity comprises a first edge that is non-vertical, the first cavity is configured to align a die towards a center of the first cavity when the die is placed off-center of the first cavity; and
a first die positioned substantially in a center of the first cavity.

2. The integrated device of claim 1, wherein the first edge is a first wall of the first cavity.

3. The integrated device of claim 1, wherein the first cavity comprises a first opening and a first base portion, wherein the first opening of the first cavity is greater than the first base portion of the first cavity.

4. The integrated device of claim 1, further comprising a redistribution portion coupled to the first die.

5. The integrated device of claim 1, wherein the first die comprises one of at least rounded edges and/or beveled edges.

6. The integrated device of claim 1, further comprising an adhesion layer between the first die and the substrate, wherein the adhesion layer is configured to couple the first die to the substrate.

7. The integrated device of claim 1, further comprising a second cavity in the substrate, the second cavity positioned in the substrate such that the second cavity is coupled to the first cavity, and the second cavity is between a base portion of the first cavity and a surface of the substrate.

8. The integrated device of claim 1, further comprising a heat sink embedded in the substrate, wherein the heat sink is embedded in the substrate such that the heat sink is between a base portion of the first cavity and a surface of the substrate.

9. The integrated device of claim 1, wherein the integrated device is one of at least a semiconductor device, an integrated package and/or a die package.

10. The integrated device of claim 1, wherein the integrated device is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

11. An apparatus comprising:
a substrate comprising a first die aligning means, wherein the first die aligning means is configured to align a die towards a center of the first die aligning means when the die is placed off-center of the die aligning means; and
a first die positioned substantially in a center of the first die aligning means.

12. The apparatus of claim 11, wherein the first die aligning means comprises a first wall that is non-vertical.

13. The apparatus of claim 11, wherein the first cavity comprises a first opening and a first base portion, wherein the first opening of the first cavity is greater than the first base portion of the first cavity.

14. The apparatus of claim 11, further comprising a redistribution portion coupled to the first die.

15. The apparatus of claim 11, wherein the first die comprises one of at least rounded edges and/or beveled edges.

16. The apparatus of claim 11, further comprising an adhesive means between the first die and the substrate, wherein the adhesive means is configured to couple the first die to the substrate.

17. The apparatus of claim 11, further comprising a cooling means in the substrate, the cooling means positioned in the substrate such that the cooling means is coupled to the first die aligning means, and the cooling means is between a base portion of the first die aligning means and a surface of the substrate.

18. The apparatus of claim 11, further comprising a heat dissipating means embedded in the substrate, wherein the heat dissipating means is embedded in the substrate such that the heat dissipating means is between a base portion of the first die aligning means and a surface of the substrate.

19. The apparatus of claim 11, wherein the apparatus is one of at least an integrated device, a semiconductor device, an integrated package and/or a die package.

20. The apparatus of claim 11, wherein the apparatus is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

21. A method for providing an integrated device, comprising:
providing a substrate;
providing a first cavity in the substrate, wherein the first cavity comprises a first edge that is non-vertical; and
providing a first die such that the first die is positioned in the first cavity.

22. The method of claim 21, wherein the first cavity is configured to align a die towards a center of the first cavity when the die is placed off-center of the first cavity.

23. The method of claim 21, wherein the first cavity comprises a first opening and a first base portion, wherein the first opening of the first cavity is greater than the first base portion of the first cavity.

24. The method of claim 21, further comprising providing a redistribution portion such that the redistribution is coupled to the first die.

25. The method of claim 21, wherein the first die comprises one of at least rounded edges and/or beveled edges.

26. The method of claim 21, further comprising providing an adhesion layer between the first die and the substrate such that the adhesion layer is configured to couple the first die to the substrate.

27. The method of claim 21, further comprising providing a second cavity in the substrate, the second cavity is positioned in the substrate such that the second cavity is coupled to the first cavity, and the second cavity is between a base portion of the first cavity and a surface of the substrate.

28. The method of claim 21, further comprising providing a heat sink such that the heat sink is embedded in the substrate, wherein the heat sink is embedded in the substrate such that the heat sink is between a base portion of the first cavity and a surface of the substrate.

29. The method of claim 21, wherein the integrated device is one of at least a semiconductor device, an integrated package and/or a die package.

30. The method of claim 21, wherein the integrated device is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.
